(19) United States
(12) Patent Application Publication
(10) Pub. No.: US 2026/0009854 A1
(43) Pub. Date: Jan. 8, 2026

(54) METHOD OF MANUFACTURING REUSE BATTERY SYSTEM AND METHOD OF OPERATING THE SAME

(71) Applicant: GS Yuasa International Ltd., Kyoto-shi (JP)

(72) Inventor: Shuichi TAKEMOTO, Kyoto-shi (JP)

(21) Appl. No.: 19/327,181

(22) Filed: Sep. 12, 2025

Related U.S. Application Data
(63) Continuation of application No. PCT/JP2024/009918, filed on Mar. 14, 2024.

(30) Foreign Application Priority Data
Mar. 27, 2023 (JP) 2023-049550

(51) Int. Cl. G01R 31/36; G01R 31/367; G01R 31/392; H01M 10/42

(52) U.S. Cl. CPC G01R 31/3647; G01R 31/367; G01R 31/392; H01M 10/425; H01M 2010/4271; H01M 2010/4278

(57) ABSTRACT

A method of manufacturing a reuse battery system includes receiving, by a management unit of a used battery, characteristic map data corresponding to a state of the used battery on or after a time when reuse of the used battery is started; verifying, by the management unit, the received characteristic map data by using an error-detecting code added to the characteristic map data; and saving, when the received characteristic map data is appropriate, the characteristic map data in a storage portion by the management unit.

### CROSS REFERENCE TO RELATED APPLICATIONS

This application claims the benefit of priority to Japanese Patent Application No. 2023-049550 filed on Mar. 27, 2023 and is a Continuation Application of PCT Application No. PCT/JP2024/009918 filed on Mar. 14, 2024. The entire contents of each application are hereby incorporated herein by reference.

### BACKGROUND OF THE INVENTION

### 1. Field of the Invention

Example embodiments of the present invention relate to methods of manufacturing (methods of constructing) reuse battery systems.

### 2. Description of the Related Art

Japanese Unexamined Patent Application Publication No. 2020-53167 discloses a method of reusing a secondary battery which enables, before removal from a vehicle, before transportation to a factory, before disassembly in a factory, or before capacity measurement, detection (selection) of a battery unsuitable for recycling (reuse).

### SUMMARY OF THE INVENTION

In recent years, attempts have been made to apply used batteries (mainly lithium-ion batteries) that have been used in primary use to secondary use such as backup power supply systems and energy storage systems.

In order to enhance reliability of operation of such a secondary use battery system (reuse battery system), various techniques have been developed.

Example embodiments of the present invention provide methods of manufacturing reuse battery systems for improving the operational reliability of the systems.

A method of manufacturing a reuse battery system according to an example embodiment of the present invention includes receiving, by a management unit of a used battery, characteristic map data corresponding to a state of the used battery on or after a time when reuse of the used battery is started; verifying, by the management unit, the characteristic map data which has been received by using an error-detecting code added to the characteristic map data; and saving, when the characteristic map data which has been received is appropriate, the characteristic map data in a storage portion by the management unit.

According to the above example embodiment of the present invention, it is possible to manufacture a reuse battery system whose operational reliability is improved by correctly saving the characteristic map data including a large number of pieces of data in the storage portion of the management unit.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a block diagram showing an example of a reuse battery system.

FIG. 2 is a diagram showing an example of arrangement of used batteries and management units in an energy storage portion.

FIG. 3 is a perspective view showing an example of a battery module.

FIG. 4 is a graph showing an example of a characteristic map (SOC-OCV map).

FIG. 5 is a conceptual diagram illustrating an example of characteristic map data (SOC-OCV map data) received by the management unit.

FIG. 6 is a flowchart showing a procedure in which the management unit saves the received characteristic map data in a storage portion.

FIG. 7 is a flowchart showing a procedure in which the management unit reads the characteristic map data from the storage portion.

### DETAILED DESCRIPTION OF THE EXAMPLE EMBODIMENTS

An outline of the example embodiments of the present invention will be described below.

A method of manufacturing a reuse battery system according to an example embodiment of the present invention includes receiving, by a management unit of a used battery, characteristic map data corresponding to a state of the used battery on or after a time when reuse of the used battery is started; verifying, by the management unit, the characteristic map data which has been received by using an error-detecting code added to the characteristic map data; and saving, when the characteristic map data which has been received is appropriate, the characteristic map data in a storage portion by the management unit.

The used battery may be a single battery cell or a battery module in which the battery cells are connected in series and/or in parallel or alternatively, may be a battery pack in which the battery cells or the battery modules are connected in series and/or in parallel. From the standpoint of reducing the labor required for disassembly, the used battery preferably is applied to a reuse battery system without changing the form (for example, a battery pack or a battery module) adopted in the primary use (for example, an in-vehicle battery system) to the extent possible.

The used battery may be, but is not limited to, a lithium-ion secondary battery. A secondary battery such as a sodium-sulfur (NaS) battery, a redox flow battery, a lithium-ion capacitor, an electric double layer capacitor, an air battery, a solid-state battery, a semi-solid battery, a nickel-hydrogen battery, an alkaline battery, a nickel-cadmium battery, a lithium polymer battery, or a lead-acid battery may be used, for example.

The time when reuse is started includes the time when a reuse battery system is manufactured (constructed) and the time when the performance of a used battery is measured. The time when reuse is started may be the time when reuse in the secondary use is started, or may be the time when reuse in the third or subsequent use is started.

According to the method described above, characteristic map data including a large number of pieces of data (for example, state of charge (SOC)-open circuit voltage (OCV) map data, which is hereinafter be referred to as SOC-OCV map data) can be correctly saved in the management unit of the used battery. As a consequence, a reuse battery system whose operational reliability is improved can be manufactured.

When a reuse battery system is to be manufactured without changing the form adopted in the primary use to the extent possible, the initial characteristic map data is saved in a management unit which has been used in the primary use provided in the battery pack or the battery module. However, the map data saved therein often does not correspond to the state, for example, the state of health (SOH), of the used battery at the time when reuse is started.

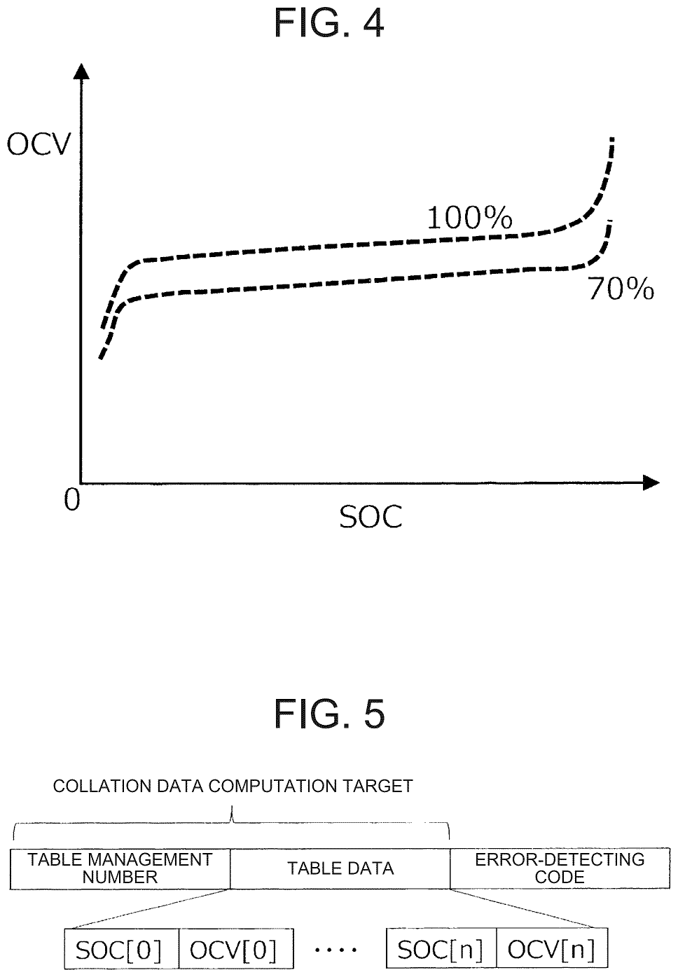

FIG. 4 shows the SOC-OCV map of batteries with different SOHs. Each curve (profile) includes a large number of pieces of data, and about one hundred pieces of data are included, for example.

In order to control the battery, in addition to the SOC-OCV map (an example of a characteristic map) for estimating the SOC from a measured voltage of the battery, a charge upper limit voltage, a discharge lower limit voltage, and the like, are also required. Each of the upper limit voltage and the lower limit voltage is one point data. As compared with such numerical values (so-called set values), the number of pieces of data forming the characteristic map such as the SOC-OCV map is very large. Thus, an error is likely to occur when the data is saved in the management unit at the time of manufacturing the reuse battery system, for example.

In FIG. 4, a curve indicated as 100% represents the initial SOC-OCV map (when the SOH is 100%) in the primary use of a battery. The curve indicated as 70% represents the SOC-OCV map to be referred to when the battery has been used and the SOH has dropped to 70%.

In a case where only the SOC-OCV map data corresponding to the SOH of 100% is saved in the management unit of the battery pack or the battery module of the primary use, that map data does not correspond to the state of the used battery at the time when reuse is started. Therefore, the SOC-OCV map data corresponding to the state (for example, the SOH of 70%) of the used battery at the time when reuse is started, is preferably saved in the management unit.

Such data saving is also performed when a used battery is managed by a new management unit instead of the management unit that has been used in the primary use.

If an error occurs at the time of saving the map data for forming the curve corresponding to the SOH of 70% in the management unit, an outlier may be stored or a curve having a shape different from that of an intended curve may be stored. In that case, the management unit cannot correctly estimate the SOC of the battery after start of the operation of the reuse battery system, and the operational reliability of the system is impaired. The same may also occur in characteristic map data other than the SOC-OCV map data.

The state (SOH, for example) of the used battery at the time when reuse is started is obtained by way of measurement (for example, capacity measurement by discharge from full charge of the battery).

Examples of the state of the battery other than the SOH include deterioration states corresponding to various deterioration mechanisms of the battery (isolation of an active material, a decrease in charge carriers (lithium ions (Li+), for example) which are involved in a charge and a discharge, an increase in electrical resistance, and a reduction in conductivity in an electrolytic solution, and the like). The deterioration state of the battery corresponding to such various deterioration mechanisms can be obtained and estimated by a simulation, on the basis of operational history data (a current history, a voltage history, a temperature history, and the like) in the primary use (or the past use up to the present time).

According to the method described above, the characteristic map data (such as the SOC-OCV map data including a large number of pieces of data), which corresponds to the state of the used battery obtained by measurement or estimation, can be correctly saved in the storage portion of the management unit through verification using the error-detecting code. Accordingly, a reuse battery system whose operational reliability is improved can be manufactured.

In the method described above, a communication portion of the reuse battery system may receive the characteristic map data from a host device, and a plurality of management units including the management unit, which are respectively provided for a plurality of groups of the used battery, may receive the characteristic map data from the communication portion.

According to the above method, each of the plurality of management units can receive the characteristic map data which is appropriate for the battery group managed by its own management unit while simplifying the configuration of the reuse battery system.

It is difficult to prepare a large number of used batteries whose residual performance is uniform. Therefore, pieces of different characteristic map data may be respectively given to the management units of the plurality of groups of batteries via the communication portion of the reuse battery system. In the secondary use such as backup power supply systems and energy storage systems, a great many used batteries are often connected in parallel to ensure the electrical capacity that is required.

The characteristic map data which is appropriate for each battery group can be given to the management unit provided for each of the battery groups that are connected in parallel.

In the methods described above, a host device may prepare the characteristic map data on the basis of measurement data of the used battery and/or a simulation result which is based on history data of a past use of the used battery.

Measurement techniques and simulation techniques for the battery are still developing. The measurement accuracy and the simulation accuracy are improving year by year, and a deterioration phenomenon of a battery, which has been formerly unknown, are clarified and modeled. By applying the measurement data based on the latest technology and the latest simulation technique to a host device, and causing the host device to estimate the state of the used battery at the time when reuse is started, and also to prepare the characteristic map data, operational reliability of the reuse battery system to be manufactured can be further improved.

A method of operating a reuse battery system according to an example embodiment of the present invention includes monitoring, by a host device, a state of a used battery after reuse of the used battery is started; receiving, by a management unit of the used battery, characteristic map data corresponding to the state which is prepared by the host device; verifying, by the management unit, the characteristic map data which has been received by using an error-detecting code added to the characteristic map data; and saving, when the characteristic map data which has been received is appropriate, the characteristic map data in a storage portion by the management unit.

According to the above-described operation method, the host device is made to monitor the state of the used battery after reuse of the used battery is started and to prepare the characteristic map data, and the characteristic map data including a large number of pieces of data is correctly saved in the storage portion of the management unit. By this feature, the operational reliability can be improved.

In the method described in the preceding paragraph, the host device may prepare the characteristic map data on the basis of measurement data after reuse of the used battery is started and/or a simulation result which is based on history data after the reuse is started.

After the reuse is started, charge and discharge different from those of an operation pattern of a previous stage (for example, at the time of the primary use) are often performed. According to the operation method of the example embodiment described above, it is possible to prepare appropriate characteristic map data by using the measurement data after the reuse is started and/or the result of simulation to which the latest technology is applied, for example, on the basis of the operational history data after the reuse is started.

Example embodiments will be described below with reference to the accompanying drawings. The present invention is not limited to the example embodiments described below.

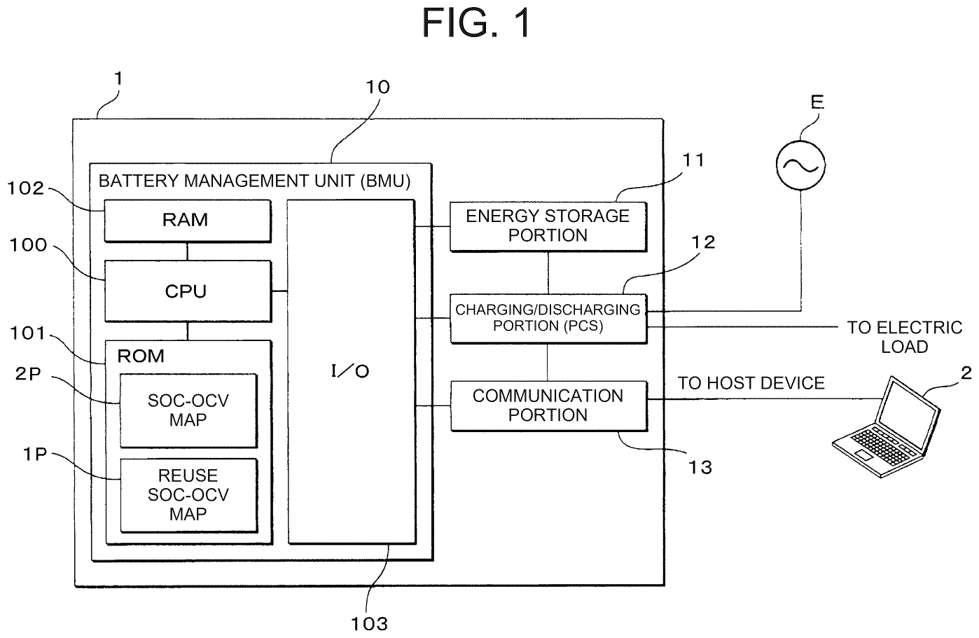

FIG. 1 illustrates a configuration of an energy storage system (ESS) 1 as a reuse battery system. The ESS 1 is provided with a battery management unit (BMU) 10, an energy storage portion 11, a power conditioner 12 as an example of a (PCS) charging/discharging portion, and a communication portion 13. The ESS 1 may be a so-called power conditioner with a storage battery. The reuse battery system may be a backup power supply system or another system (a battery system to drive a movable body, for example), instead of the ESS 1.

The BMU 10 includes a central processing unit (CPU) 100, a read-only memory (ROM) 101, a random-access memory (RAM) 102, and an input/output (I/O) 103.

The CPU 100 is configured or programmed to include an execution portion, and to sequentially read firmware stored in the ROM 101 to execute control processing according to a control procedure defined by the firmware. The ROM 101 is, in principle, a read-only, non-transitory memory from the perspective of the CPU 100. The ROM 101 is, for example, an electrically erasable programmable read-only memory (EEPROM). In the ROM 101, a previously defined SOC-OCV map 2P and a reuse SOC-OCV map 1P are stored. The previously defined SOC-OCV map 2P may be continued to be saved in the ROM which is embedded in the CPU 100.

The RAM 102 is a transitory memory used by the CPU 100 for computation. The CPU 100 proceeds with processing while saving a result of the computation to the RAM 102 and reading the same from the RAM 102. Data stored in the RAM 102 is volatilized by a restart of the BMU 10.

The energy storage portion 11 includes a used battery. The energy storage portion 11 is connected to a system power supply E via the PCS 12. The energy storage portion 11 may be connected to a power production source (a solar panel or other renewable energy generators, for example), which is not illustrated, via the PCS 12. The BMU 10 may receive supply of power from the energy storage portion 11.

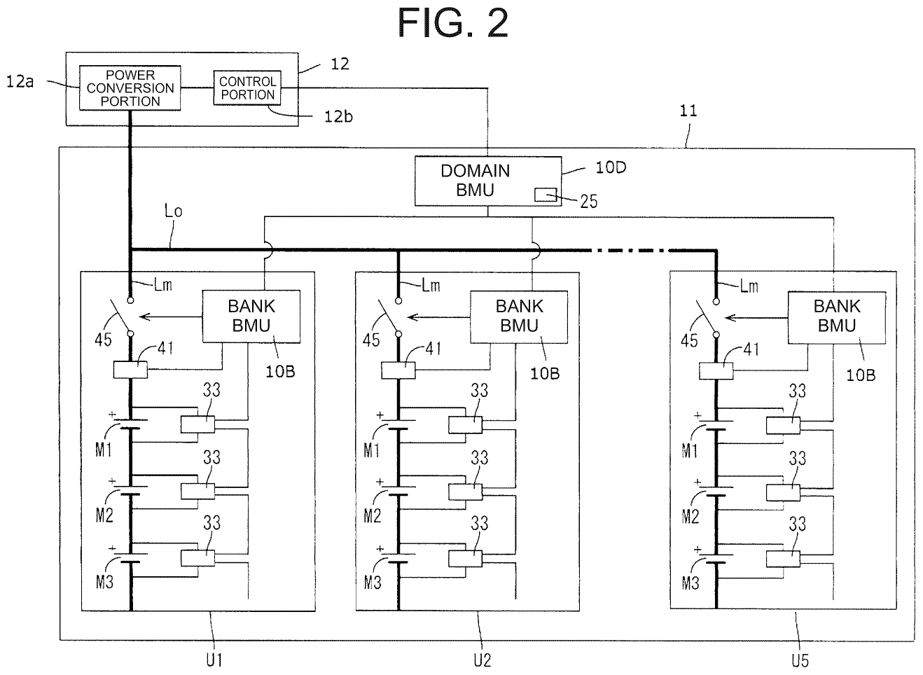

The PCS 12 includes an inverter and/or a converter as a power conversion portion 12a (see FIG. 2). The PCS 12 is connected to an electric load, and executes, for example, supply of power from the system power supply E to the electric load, a charge to the energy storage portion 11 from the system power supply E, supply of power from the energy storage portion 11 to the electric load (including an assist discharge when power is to be supplied from the system power supply E to the electric load), and the like. The PCS 12 may be connected to an alternating-current power grid (AC grid) or to a direct-current power grid (DC grid).

The communication portion 13 is a communication device configured or programmed to communicate with a host device 2. The host device 2 may be an external storage medium (a USB flash drive, for example). The communication portion 13 may be, for example, a network interface card, or may have a configuration which enables the external storage medium to be mounted thereon. The BMU 10 receives data (reuse SOC-OCV map data, for example) from the host device 2 via the communication portion 13.

The host device 2 may be a terminal device (a maintenance terminal device, for example) configured or programmed to transmit update data for the SOC-OCV map to the ESS 1 via a local network. Alternatively, the host device 2 may be a server apparatus (a remote monitoring server, for example) configured or programmed to provide an instruction to the ESS 1 via a communication network including the Internet or collects data from the ESS 1.

FIG. 2 shows an example of arrangement of used batteries and the BMU 10 in the energy storage portion 11. The energy storage portion 11 includes a plurality of used battery groups U1, U2, . . . in a battery board or a container. A plurality of battery groups U are connected in parallel to a common current-carrying path Lo extending from the power conversion portion 12a of the PCS 12. In the present example embodiment, five used battery groups U1 to U5 are connected in parallel, but the number of parallel connections is not limited to the above. As illustrated in FIG. 2, the PCS may be arranged outside the container.

Each of the battery groups U includes a plurality of battery modules M connected in series, a current sensor 41, and a current cutoff device 45. Each of the battery modules M may be configured by connecting battery cells (also referred to as cells) in series. A group in which the plurality of battery modules M are connected in series will be hereinafter referred to as a bank.

In the energy storage portion 11 of the present example embodiment, a bank BMU 10B is provided for each bank U, and a domain BMU 10D is provided for a group (hereinafter referred to as a domain) in which a plurality of banks U are connected in parallel. The domain BMU 10D can communicate with the bank BMU 10B via a communication bus (a CAN bus, for example).

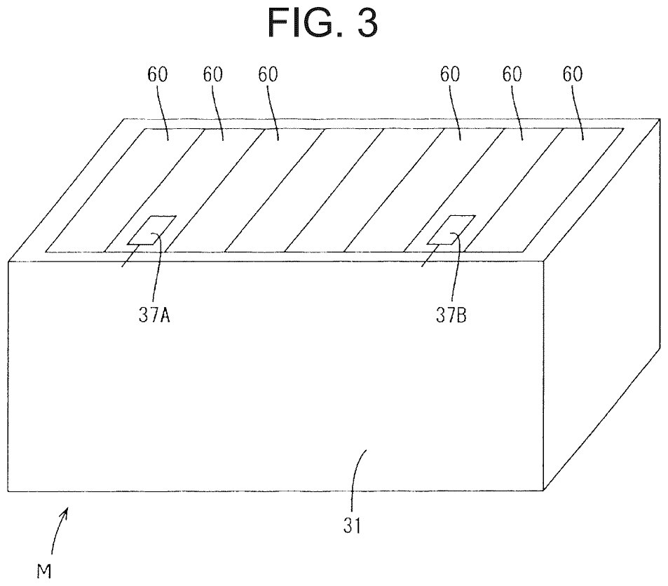

In each bank U, a cell management unit (CMU) 33, which is provided for each battery module M, communicates with the bank BMU 10B connected to these CMUs 33 via a serial communication interface such as RS-232C. The CMU 33 may include a voltage sensor (not shown) to measure the voltage of each cell and a temperature sensor 37 (see FIG. 3). The bank BMU 10B acquires current data measured for each bank, and voltage data and temperature data measured by the CMU 33 of each battery module M.

The domain BMU 10D may aggregate pieces of battery state data acquired by the respective bank BMUs 10B and store the aggregated battery state data in a storage portion 25. The storage portion 25 may be provided outside the domain BMU 10D.

Although FIG. 2 illustrates an example in which the domain BMU 10D is connected to a control portion 12b of the PCS 12, the domain BMU 10D may be connected to the communication portion 13 (see FIG. 1). Alternatively, the bank BMU 10B may be connected to the communication portion 13 via the CAN bus without intervening the domain BMU 10D.

As illustrated in FIG. 3, the battery module M of the present example embodiment includes a case 31 which accommodates therein a plurality of battery cells 60 that are arranged adjacent to each other, and a plurality of temperature sensors 37A and 37B which measure the temperature of the battery cells 60. The battery cell 60 is a prismatic cell in which an electrode body and a non-aqueous electrolyte are accommodated in a case having a rectangular or substantially rectangular parallelepiped shape. The battery cell may alternatively be a pouch cell or a cylindrical cell. The battery cell 60 of the present example embodiment is a lithium-ion secondary battery cell. The battery module M of the present example embodiment is applied to a reuse battery system almost as it is in substantially the same form as that of previous use (for example, primary use). That is, the battery module M is applied to the reuse battery system without disassembling the CMU 33 and the temperature sensor 37 that have been used in the previous use.

In the present example embodiment, the host device 2 (see FIG. 1) prepares characteristic map data corresponding to the state of the used battery on or after the time when reuse of the used battery is started, and the bank BMU 10B provided for each bank U (see FIG. 2) receives the characteristic map data. The host device 2 may prepare a plurality of pieces of characteristic map data corresponding to the assumed states of the used battery at a plurality of points of time (in future) on or after the time when reuse of the used battery is started.

At the time of shipment of a battery for primary use (for example, a driving battery system mounted on an electric vehicle), pieces of characteristic map data corresponding to various battery states are not sufficiently prepared. For example, it takes a long time and much labor to prepare the SOC-OCV map data according to various SOHs (for example, 80%, 75%, 70%, 65%, 60% . . . ). Further, at the time of the shipment of a battery for primary use, reuse of the battery is not assumed. Therefore, at the time of the shipment of a battery for primary use, only a limited number of pieces of characteristic data, including the SOC-OCV map data corresponding to the SOH of 100%, are saved in a management unit for the primary use.

As the BMU 10, even when a BMU different from the BMU used for the primary use is used (i.e., when the BMU is replaced), only a limited number of pieces of characteristic data are saved in the BMU 10 after the replacement.

In accordance with a decrease in the SOH of the battery, it is necessary to switch the SOC-OCV map to be referred to for SOC estimation. In the present example embodiment, the host device 2 (see FIG. 1) prepares the characteristic map data corresponding to the state of the used battery on or after the time when reuse of the used battery is started, and transmits the characteristic map data to the domain BMU 10D or the bank BMU 10B.

FIG. 5 shows the SOC-OCV map data as an example of the characteristic map data prepared by the host device 2. The map data includes a table management number, table data in which the SOC and the OCV are stored in association with each other in a table, and an error-detecting code.

Examples of the error-detecting code include a checksum and a cyclic redundancy code (CRC). From the standpoint of verification accuracy, CRC-16 may be adopted, but the error-detecting code to be adopted is not limited to the above.

The table management number may be any number as long as that number can identify the table data. By referring to the table management number, it is possible to confirm whether the data adopted in the bank BMU 10B is new map data or previously defined map data is continued to be used in the bank BMU 10B.

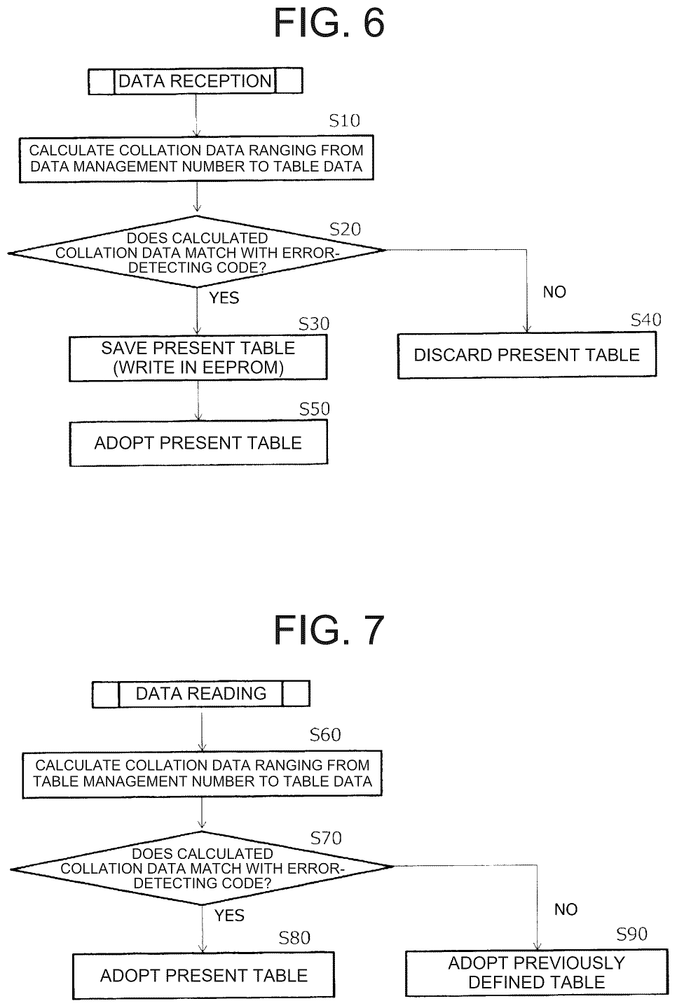

FIG. 6 shows a procedure in which the bank BMU 10B saves the SOC-OCV map data received from the host device 2 in the ROM 101.

The bank BMU 10B calculates collation data, which ranges from the table management number to the table data, by a calculation technique corresponding to the error-detecting code (step S10).

The bank BMU 10B determines whether the calculated collation data matches with the error-detecting code (step S20). If they match (S20: YES), it is assumed that the received SOC-OCV map data is appropriate, and the map data is saved in the ROM 101 (step S30).

If the bank BMU 10B determines that the calculated collation data does not match with the error-detecting code (S20: NO), the bank BMU 10B discards the received SOC-OCV map data. In this case, the bank BMU 10B continues to use the previously defined SOC-OCV map data.

FIG. 7 shows a procedure for reading an SOC-OCV table saved in the ROM 101.

The bank BMU 10B calculates the collation data, which ranges from the table management number to the table data, by the calculation technique corresponding to the error-detecting code (step S60).

The bank BMU 10B determines whether the calculated collation data matches with the error-detecting code (step S70). If they match (S70: YES), it is assumed that new SOC-OCV map data that has been read is appropriate, and the new map data is adopted to estimate the SOC from a measured voltage of the used battery.

If the bank BMU 10B determines that the calculated collation data does not match with the error-detecting code (S70: NO), the bank BMU 10B adopts the previously defined SOC-OCV map data.

An example embodiment of a method of manufacturing a reuse battery system has been described above. Next, an example embodiment of a method of operating the reuse battery system will be described.

In a method of operating the reuse battery system (ESS 1), the host device 2 (a remote monitoring server, for example) monitors the state of the used battery (the energy storage portion 11) illustrated in FIG. 1 after reuse of the used battery is started.

The management unit (the bank BMU 10B) of the used battery receives the characteristic map data (see FIG. 5) corresponding to the state of the used battery after reuse of the used battery is started which is prepared by the host device 2.

The management unit verifies the received characteristic map data using the error-detecting code added to the characteristic map data.

When the received characteristic map data is appropriate, the management unit saves the characteristic map data in a storage portion (the ROM 101). The management unit uses the new characteristic map data to control the used battery.

In the reuse battery system, the battery is deteriorated as compared with that of the previous use. Therefore, it is necessary to increase the reliability of operation by applying various techniques.

In the above example embodiment, remote monitoring is realized by using the communication portion 13 provided in the ESS 1 and the host device 2. Further, in the above example embodiment, the host device 2 prepares the characteristic map data corresponding to the state of the used battery after reuse is started, and the management unit receives the characteristic map data and stores that characteristic map data through the verification using the error-detecting code.

By correctly saving the characteristic map data including a large number of pieces of data in the storage portion of the management unit, the operational reliability of the reuse battery system can be improved.

Through the remote monitoring, if an operation deviating from a load pattern assumed at the time of manufacturing the reuse battery system is conducted, the host device can detect such an event. Therefore, it is possible to take appropriate measures at an early stage, such as reconsidering the operation of the reuse battery system, increasing the number of banks, and replacing the battery module M or the bank U whose deterioration has progressed.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A method of manufacturing a reuse battery system, the method comprising:
receiving, by a management unit of a used battery, characteristic map data corresponding to a state of the used battery on or after a time when reuse of the used battery is started;
verifying, by the management unit, the characteristic map data which has been received by using an error-detecting code added to the characteristic map data; and
saving, when the characteristic map data which has been received is appropriate, the characteristic map data in a storage portion by the management unit.

2. The method of manufacturing a reuse battery system according to claim 1, wherein a communication portion of the reuse battery system receives the characteristic map data from a host device, and a plurality of management units including the management unit, which are respectively provided for a plurality of groups of the used battery, receive the characteristic map data from the communication portion.

3. The method of manufacturing a reuse battery system according to claim 1, wherein a host device prepares the characteristic map data, based on at least one of measurement data of the used battery or a simulation result which is based on history data of a past use of the used battery.

4. A method of operating a reuse battery system, the method comprising:
monitoring, by a host device, a state of a used battery after reuse of the used battery is started;
receiving, by a management unit of the used battery, characteristic map data corresponding to the state which is prepared by the host device;
verifying, by the management unit, the characteristic map data which has been received by using an error-detecting code added to the characteristic map data; and
saving, when the characteristic map data which has been received is appropriate, the characteristic map data in a storage portion by the management unit.

5. The method of operating a reuse battery system according to claim 4, wherein the host device prepares the characteristic map data, based on at least one of measurement data after reuse of the used battery is started or a simulation result which is based on history data after the reuse is started.
